(19) United States
(12) Patent Application Publication
(10) Pub. No.: US 2001/0008811 A1
(43) Pub. Date: Jul. 19, 2001

(54) Card connector

(75) Inventors: Takayuki Soga, Tokyo (JP); Shinichi Matsuzaki, Tokyo (JP); Tomisaburo Yamaguchi, Tokyo (JP)

Correspondence Address: HELFGOTT & KARAS, P.C., Empire State Building, 60th Floor, New York, NY, 10118-0110, US

(73) Assignee: Sony Computer Entertainment Inc.

(21) Appl. No.: 09/759,174

(22) Filed: Jan. 12, 2001

(30) Foreign Application Priority Data
Jan. 18, 2000 (JP) 2000-008828

(51) Int. Cl. H05K 1/00; H01R 12/00; H01R 24/00

(52) U.S. Cl. 439/79; 439/630

(57) ABSTRACT

A card connector is obtained which can realize a small size and a low profile of an apparatus. The connector comprises a plurality of pins and a support member. The pin has a card-connecting section connected to a PC card, and a board-installing section installed to a circuit board. The pin has a card-connecting section side bent section and a board-installing section side bent section. The position of the card-connecting section is lower than that of a section disposed between the card-connecting section side bent section and the board-installing section side bent section. In this arrangement, the support member is formed such that the position of a lower outer wall surface of a slot section is lower by a height hc than the position of a lower surface of a board-installing section support section for supporting the board-installing section.

### BACKGROUND OF THE INVENTION

1. Field of the Invention

The present invention relates to a connector for a card. In particular, the present invention relates to a card connector which can realize a small size and a low profile of an apparatus into which the card connector is incorporated.

2. Description of the Related Art

FIG. 4 shows a conventional connector 1 for a PC card. As shown in FIG. 4, the connector 1 comprises a plurality of pins 4 for electrically connecting the card 2 to a circuit board 3, and a support member 5 made of resin for supporting the pins 4.

The pin 4 has a forward end section 4a and a rearward end section 4b. The forward end section 4a is inserted into a socket 2a of the card 2 for being connected to the card 2. The rearward end section 4b is installed to the circuit board 3 by means of, for example, soldering. The pin 4 is bent at the right angle at a bent section 4c which is provided between the forward end section 4a and the rearward end section 4b. That is, the pin 4 is formed to have a substantially L-shaped configuration.

The support member 5 includes a slot section 5a, a forward end support section 5b, a bent section-protecting section 5c, and a rearward end support section 5d. The slot section 5a forms a slot 7 for inserting the card 2 thereinto. The forward end support section 5b is arranged at the bottom (closed end) of the slot 7 for supporting the pins 4 on the side of the forward end sections 4a. The bent section-protecting section 5c surrounds portions disposed in the vicinity of the bent sections 4c of the pins 4. The rearward end support section 5d supports the pins 4 on the side of the rearward end sections 4b. The support member 5 is formed so that the shape of its side surface may have a substantially rectangular configuration.

In this arrangement, the forward end section 4a of the pin 4 protrudes inside the slot 7 so that the forward end section 4a is parallel to the inner wall surface of the slot 7. On the other hand, the rearward end section 4b of the pin 4 protrudes downwardly from the rearward end support section 5d as shown in FIG. 4 so that the rearward end section 4b is perpendicular to the forward end section 4a. That is, the lower surface of the rearward end support section 5d is an installation surface 9 which is opposed to or contacts with the circuit board 3 when the connector 1 is attached to the circuit board 3.

The installation surface 9 and the lower surface of the slot section 5a are formed so as to be disposed substantially on an identical plane. In this arrangement, the height dimension hb is about 6.2 mm, assuming that the thickness ha of the circuit board 3 is 1 mm. The height dimension hb ranges from the lower surface of the circuit board 3 to the upper surface of the connector 1.

The connector 1 described above is formed such that the installation surface 9 and the lower surface of the slot section 5a are disposed substantially on the identical plane. Accordingly, when the connector 1 is attached to the circuit board 3, the substantially whole support member 5 is located at a position higher than the surface position of the circuit board 3. Therefore, the following problem arises that it is difficult to realize a small size and a low profile of an apparatus into which the connector 1 is incorporated.

### SUMMARY OF THE INVENTION

The present invention has been made in order to solve above problem. Specifically, an object of the present invention is to provide a card connector which can realize a small size and a low profile of an apparatus.

According to the present invention, there is provided a card connector comprising a plurality of pins for electrically connecting a detachable card and a circuit board; and a support member for supporting the pins; wherein the support member has a slot section for inserting the card thereinto; and the pin includes a card-connecting section which is located on a side of the slot section, for being connected to the card; a board-installing section which is installed to the circuit board; and bent sections which are located between the card-connecting section and the board-installing section and which are formed such that the card-connecting section is substantially parallel to a surface of the circuit board, and the card-connecting section is deviated toward or beyond an extension plane of the surface of the circuit board, in a state in which the board-installing section is installed to the circuit board; and wherein the slot section is formed corresponding to bending of the bent sections such that the slot section is deviated toward or beyond the extension plane of the surface of the circuit board in the state in which the board-installing section is installed to the circuit board.

In this arrangement, the bent section has a card-connecting section side bent section which is formed by folding, in a substantially step-shaped configuration, a portion of the pin disposed in the vicinity of the card-connecting section.

The bent section has a board-installing section side bent section which is formed by folding, in a substantially L-shaped configuration, a portion of the pin disposed in the vicinity of the board-installing section; and a section of the pin, which is disposed between the card-connecting section side bent section and the board-installing section side bent section, is substantially parallel to the surface of the circuit board in the state in which the board-installing section is installed to the circuit board.

The support member includes a card-connecting section support section which is located at a bottom of the slot section, for supporting a portion of the pin disposed in the vicinity of the card-connecting section; and a board-installing section support section for supporting a portion of the pin disposed in the vicinity of the board-installing section; wherein the board-installing section support section has an installation surface which contacts with the surface of the circuit board or is opposed to the surface of the circuit board in the state in which the board-installing section is installed to the circuit board.

When the card connector is constructed as described above, a small size and a low profile of an apparatus into which the card connector is incorporated can be realized.

The card may be a PCMCIA card.

The above and other objects, features, and advantages of the present invention will become more apparent from the following description when taken in conjunction with the accompanying drawings in which a preferred embodiment of the present invention is shown by way of illustrative example.

### BRIEF DESCRIPTION OF THE DRAWINGS

FIG. 1 shows a plan view illustrating an arrangement of a card connector to which an embodiment of the present invention is applied;

FIG. 2 shows a longitudinal sectional view taken along a line II-II illustrating the connector shown in FIG. 2;

FIG. 3 shows a longitudinal sectional view illustrating the connector attached to a circuit board, and a PC card installed to the connector; and

FIG. 4 shows a longitudinal sectional view illustrating an arrangement of a conventional connector.

### DESCRIPTION OF THE PREFERRED EMBODIMENTS

An embodiment of the present invention will be explained below with reference to the drawings.

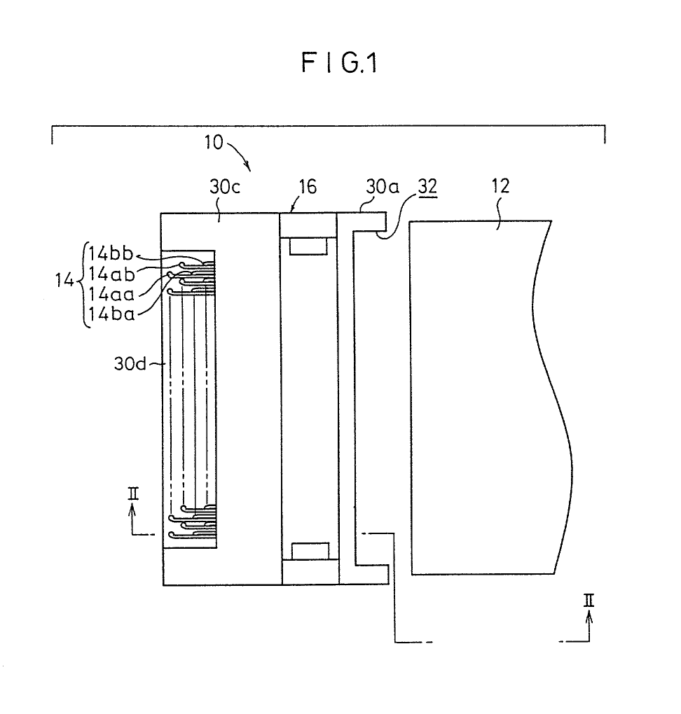

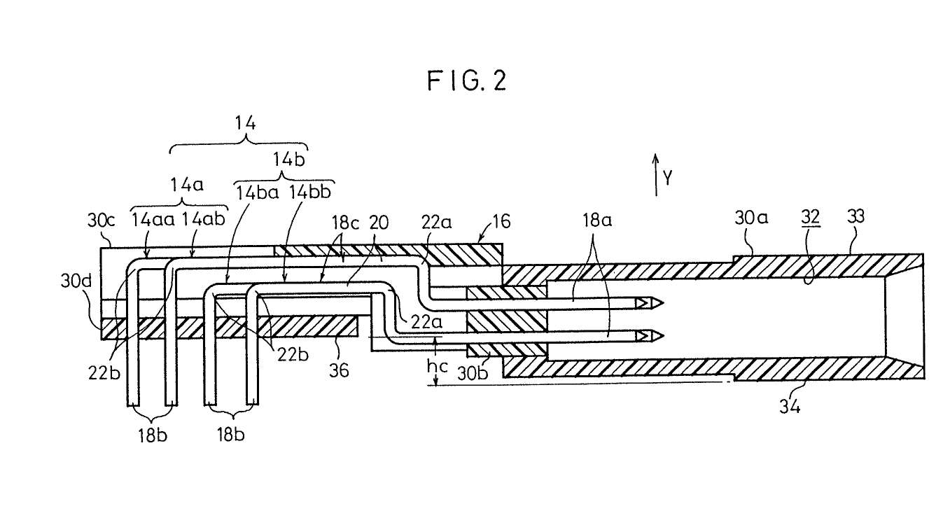

FIGS. 1 and 2 shows an arrangement of a card connector (hereinafter simply referred to as “connector” as well) 10 to which an embodiment of the present invention is applied. The connector 10 according to this embodiment corresponds to a PCMCIA card (PC card) 12 which conforms to the type II of the standard of PCMCIA (Personal Computer Memory Card International Association).

The connector 10 comprises a plurality of pins 14 for electrically connecting the detachable PC card 12 to a circuit board 40 described later on, and a support member 16 which is made of, for example, resin for supporting the pins 14.

The pins 14 include a plurality of (thirty-four) mutually parallel pins 14a which are disposed on the upper side as shown in FIG. 2, and a plurality of (thirty-four) mutually parallel pins 14b which are disposed on the lower side as shown in FIG. 2. As shown in FIG. 1, the pins 14a, 14b include pins 14aa, 14ab and pins 14ba, 14bb which are arranged so that they are alternately deviated in the inserting direction for the PC card 12 respectively.

Each of the pins 14 has a card-connecting section 18a, a board-installing section 18b, and an intermediate section 18c. The card-connecting section 18a is a portion disposed on the side of a first end to be inserted into a socket 42 of the PC card 12 as described later on and connected to the PC card 12. The board-installing section 18b is a portion disposed on the side of a second end to be installed to the circuit board 40 as described later on. The intermediate section 18c is positioned between the card-connecting section 18a and the board-installing section 18b.

The intermediate section 18c includes a card-connecting section side bent section 22a and a board-installing section side bent section 22b. The card-connecting section side bent section 22a is formed at a portion of the intermediate section 18c disposed on the side of the card-connecting section 18a. The board-installing section side bent section 22b is formed at a portion of the intermediate section 18c disposed on the side of the board-installing section 18b.

The card-connecting section side bent section 22 is formed by folding the pin 14 in a substantially step-shaped configuration so that the side of the card-connecting section 18a is disposed downwardly. On the other hand, the board-installing section side bent section 22b is formed by folding the pin 14 in a substantially L-shaped configuration so that the side of the board-installing section 18b is directed downwardly. The respective bending angles of the card-connecting section side bent section 22a and the board-installing section side bent section 22b are approximately the right angle.

In this arrangement, the height position (position in the vertical direction in FIG. 2) of the card-connecting section 18a is deviated so that the card-connecting section 18a is lower than the portion of the intermediate section 18c disposed between the card-connecting section side bent section 22a and the board-installing section side bent section 22b. The portion, which is disposed between the card-connecting section side bent section 22a and the board-installing section side bent section 22b, is substantially parallel to the card-connecting section 18a. The card-connecting section 18a and the board-installing section 18b are substantially perpendicular to one another as viewed in side view.

As shown in FIG. 2, the support member 16 is provided with a slot section 30a. The slot section 30a is formed with a slot 32 into which the PC card 12 is inserted. An upper outer wall surface 33 and a lower outer wall surface 34 of the slot section 30a are formed to be substantially parallel to an upper inner wall surface and a lower inner wall surface of the slot 32 respectively.

The support member 16 is provided with a card-connecting section support section 30b which constitutes the bottom (closed end) of the slot 32 and which supports portions of the respective pins 14 disposed in the vicinity of the card-connecting sections 18a.

The support member 16 further comprises an intermediate section-protecting section 30c which surrounds the intermediate sections 18c of the respective pins 14, and a board-installing section support section 30d which supports portions of the respective pins 14 disposed in the vicinity of the board-installing sections 18b.

The board-installing section support section 30d is formed to have a substantially plate-shaped configuration, and it is arranged so that its lower surface 36 may be mutually parallel to the lower outer wall surface 34 of the slot section 30a. The board-installing section support section 30d is arranged so that the height position (position in the vertical direction in FIG. 2) of the lower outer wall surface 34 of the slot section 30a may be disposed on the lower side lower than the position of the lower surface 36 of the board-installing section support section 30d by a height hc (about 1.0 mm).

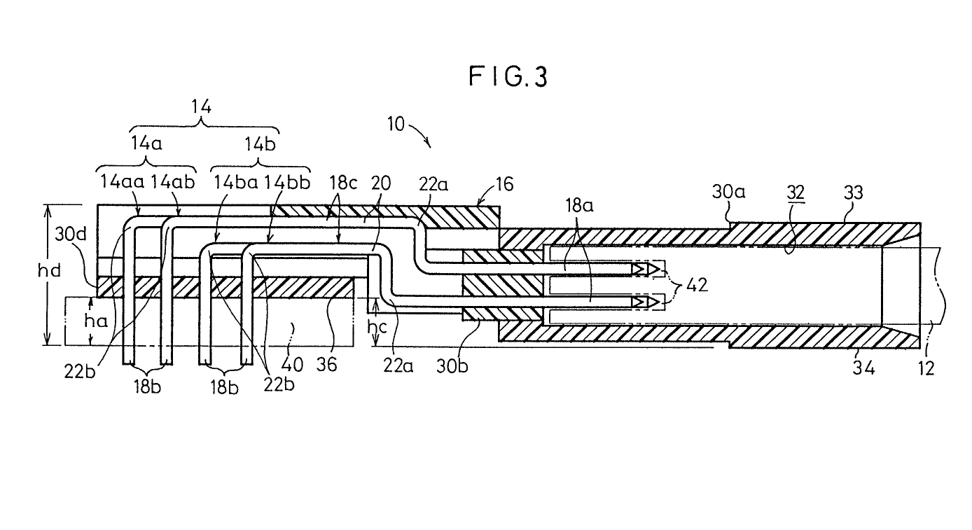

FIG. 3 shows the connector 10 attached to the circuit board 40 and the PC card 12 installed to the connector 10.

As shown in FIG. 3, the card-connecting sections 18a of the respective pins 14 are supported by the card-connecting section support section 30b and protrude inside the slot 32 parallel to the inner wall surface of the slot 32. The card-connecting sections 18a are inserted into the sockets 42 of the PC card 12 installed in the slot 32, thereby being connected to the PC card 12.

The board-installing sections 18b of the respective pins 14 are supported by the board-installing section support section 30d and protrude downwardly from the board-installing section support section 30d as shown in FIG. 3. The board-installing sections 18b of the respective pins 14 are arranged so as to be laterally aligned as shown in FIG. 3 from the side of the card-connecting sections 18a in an order of the pins 14aa, 14ab, 14ba, 14bb.

The board-installing sections 18b are inserted into unillustrated holes formed in the circuit board 40 respectively. The board-installing sections 18b are installed to the circuit board 40 by means of, for example, soldering. That is, the ends of the board-installing sections 18 are directed in the direction of installation with respect to the circuit board 40. The lower surface 36 of the board-installing section support section 30d serves as an installation surface which contacts with the circuit board 40 or is opposed to the circuit board 40.

The slot section 30a of the connector 10 protrude outwardly from the end of the circuit board 40 in the state in which the board-installing section 18b is installed to the circuit board 40. The card-connecting section 18a is deviated toward or beyond the extension surface of the upper surface of the circuit board 40 corresponding to the bending of the card-connecting section side bent section 22a. That is, the card-connecting section 18a is deviated such that the card-connecting section 18a approaches the extension surface of the upper surface of the circuit board 40, or the card-connecting section 18a deviated beyond the extension surface and it is further separated from the extension surface.

The slot section 30a is deviated toward or beyond the extension surface of the upper surface of the circuit board 40 corresponding to the deviation of the card-connecting section 18a. Specifically, the slot section 30a is arranged to be depressed downwardly as compared with the extension surface of the upper surface of the circuit board 40.

The card-connecting section 18a of the pin 14 and the portion of the pin 14 between the card-connecting section side bent section 22a and the board-installing section side bent section 22b are substantially parallel to the upper surface of the circuit board 40.

It is now assumed that the thickness ha of the circuit board 40 is, for example, 1 mm. The thickness of the connector 10 including the circuit board 40, i.e., the height dimension hd ranging from the lower surface of the circuit board 40 to the upper surface of the connector 10 is about 6.2 mm.

As described above, the card connector 10, to which the embodiment of the present invention is applied, is formed such that the position of the card-connecting section 18a is low owing to the card-connecting section side bent section 22a provided between the card-connecting section 18a and the board-installing section 18b. Accordingly, the support member 16 can be formed such that the lower outer wall surface 34 of the slot section 30a is lower than the position of the lower surface 36 of the board-installing section support section 30d as the installing surface to the circuit board 40, for example, by the same height hc (about 1.0 mm) as the thickness ha of the circuit board 40.

In this arrangement, the position of the lower outer wall surface 34 of the connector 10 can be depressed up to the position of the lower surface of the circuit board 40 in the state in which the connector 10 is installed to the circuit board 40. Accordingly, even when there is no sufficient space over the upper surface position of the circuit board 40, the connector 10 can be installed to the circuit board 40 to arrange the slot 32 inside an apparatus into which the connector 10 is incorporated. That is, it is possible to increase the degree of freedom of the apparatus into which the connector 10 is incorporated. Further, a low profile and a small size of the apparatus can be realized.

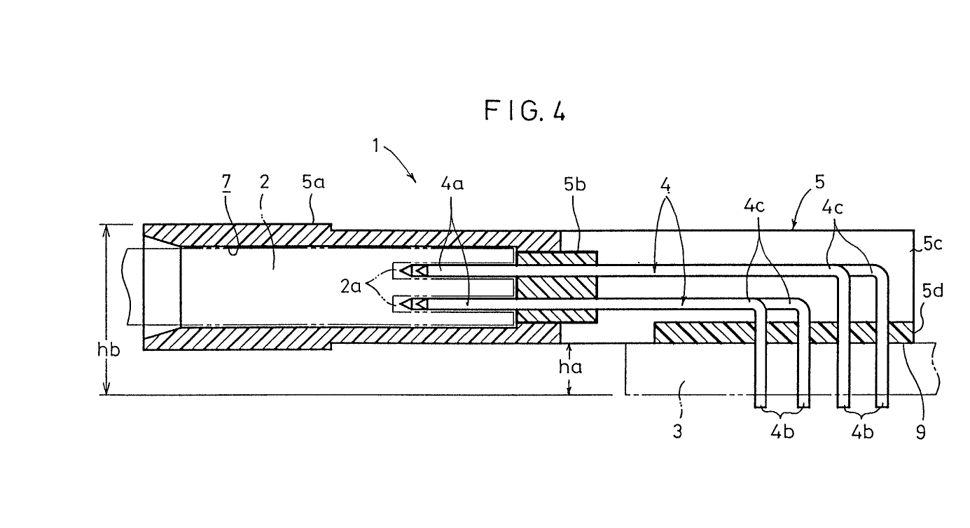

The thickness dimension of the slot section 30a including the thickness of the circuit board 40 is smaller than that of the connector 1 shown in FIG. 4. Therefore, in the case of the connector 10 according to this embodiment, it is possible to realize a lower profile and a smaller size of the apparatus into which the connector 10 is incorporated, especially of the portion at which the slot 32 is arranged.

This feature will be explained below more specifically. The space (space corresponding to the thickness ha of the circuit board 3), which is disposed under the slot section 5a of the connector 1 shown in FIG. 4 concerning the conventional technique, is usually the dead space. On the contrary, in the case of the connector 10 according to this embodiment, as shown in FIG. 3, the dead space is occupied by the portion including the lower outer wall of the slot section 30a. Thus the dead space is effectively utilized. As a result, it is possible to provide the utilizable space over the upper outer wall surface 33 of the slot section 30a.

For example, it is possible to decrease, corresponding to the amount the utilizable space, the thickness of the surface portion of the apparatus in which the connector 10 is mounted, on the side of the plug port for the PC card 12, of the slot 32.

According to the present invention, the card connector can be formed so that the height dimension including the circuit board may be decreased when the card connector is installed to the circuit board. Therefore, it is possible to realize the small size and the low profile of the apparatus into which the card connector is incorporated.

What is claimed is:

1. A card connector comprising:
a plurality of pins for electrically connecting a detachable card and a circuit board; and
a support member for supporting said pins, wherein:
said support member has a slot section for inserting said card thereinto, and said pin includes:
a card-connecting section which is located on a side of said slot section, for being connected to said card;
a board-installing section which is installed to said circuit board; and
bent sections which are located between said card-connecting section and said board-installing section and which are formed such that said card-connecting section is substantially parallel to a surface of said circuit board, and said card-connecting section is deviated toward or beyond an extension plane of said surface of said circuit board, in a state in which said board-installing section is installed to said circuit board, and wherein:
said slot section is formed corresponding to bending of said bent sections such that said slot section is deviated toward or beyond said extension plane of said surface of said circuit board in said state in which said board-installing section is installed to said circuit board.

2. The card connector according to claim 1, wherein said bent section has a card-connecting section side bent section which is formed by folding, in a substantially step-shaped configuration, a portion of said pin disposed in the vicinity of said card-connecting section.

3. The card connector according to claim 2, wherein said bent section has a board-installing section side bent section which is formed by folding, in a substantially L-shaped configuration, a portion of said pin disposed in the vicinity of said board-installing section; and
a section of said pin, which is disposed between said card-connecting section side bent section and said board-installing section side bent section, is substantially parallel to said surface of said circuit board in said state in which said board-installing section is installed to said circuit board.

4. The card connector according to claim 1, wherein said support member includes:
a card-connecting section support section which is located at a bottom of said slot section, for supporting a portion of said pin disposed in the vicinity of said card-connecting section; and
a board-installing section support section for supporting a portion of said pin disposed in the vicinity of said board-installing section, and wherein:
said board-installing section support section has an installation surface which contacts with said surface of said circuit board or is opposed to said surface of said circuit board in said state in which said board-installing section is installed to said circuit board.

5. The card connector according to claim 2, wherein said support member includes:
a card-connecting section support section which is located at a bottom of said slot section, for supporting a portion of said pin disposed in the vicinity of said card-connecting section; and
a board-installing section support section for supporting a portion of said pin disposed in the vicinity of said board-installing section, and wherein:
said board-installing section support section has an installation surface which contacts with said surface of said circuit board or is opposed to said surface of said circuit board in said state in which said board-installing section is installed to said circuit board.

6. The card connector according to claim 3, wherein said support member includes:
a card-connecting section support section which is located at a bottom of said slot section, for supporting a portion of said pin disposed in the vicinity of said card-connecting section; and
a board-installing section support section for supporting a portion of said pin disposed in the vicinity of said board-installing section, and wherein:
said board-installing section support section has an installation surface which contacts with said surface of said circuit board or is opposed to said surface of said circuit board in said state in which said board-installing section is installed to said circuit board.

7. The card connector according to claim 1, wherein said card is a PCMCIA card.

8. The card connector according to claim 2, wherein said card is a PCMCIA card.

9. The card connector according to claim 3, wherein said card is a PCMCIA card.

10. The card connector according to claim 4, wherein said card is a PCMCIA card.

11. The card connector according to claim 5, wherein said card is a PCMCIA card.

12. The card connector according to claim 6, wherein said card is a PCMCIA card.
